(19) United States
(12) Patent Application Publication
(10) Pub. No.: US 2025/0140685 A1
(43) Pub. Date: May 1, 2025

(54) INTEGRATED CIRCUIT DEVICE AND METHOD FOR FABRICATING THE SAME

(71) Applicant: TAIWAN SEMICONDUCTOR MANUFACTURING COMPANY, LTD., Hsinchu (TW)

(72) Inventors: Chrong Jung LIN, Hsinchu City (TW); Ya-Chin KING, Taipei City (TW); Gui-Sheng CHAO, Taichung City (TW)

(73) Assignee: TAIWAN SEMICONDUCTOR MANUFACTURING COMPANY, LTD., Hsinchu (TW)

(21) Appl. No.: 18/497,643

(22) Filed: Oct. 30, 2023

(51) Int. Cl. H01L 23/522; H01L 21/768; H01L 23/528; H01L 27/07

(52) U.S. Cl. CPC H01L 23/5226; H01L 21/76816; H01L 21/76877; H01L 23/5283; H10D 84/813

(57) ABSTRACT

An integrated circuit device includes a first metallization layer, a second metallization layer, and a first metal via. The first metallization layer comprises two adjacent first metal lines. The second metallization layer is over the first metallization layer, wherein the second metallization layer comprises a second metal line. The first metal via is connected with a bottom of the second metal line. The first metal via is between the first metal lines and misaligned with the first metal lines in a top view.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of a parallel-type capacitor in an integrated circuit according to some embodiments of the present disclosure.

FIG. 1B is a schematic top view of the parallel-type capacitor of FIG. 1A.

FIG. 1C is a schematic cross-sectional view of the parallel-type capacitor taken along line C-C in FIG. 1B.

FIG. 1D is a schematic cross-sectional view of the parallel-type capacitor taken along line D-D in FIG. 1B.

FIGS. 2A-21 illustrate a method for fabricating an integrated circuit device at various intermediate stages of manufacture according to some embodiments of the present disclosure.

FIG. 3A is a cross-sectional view of an integrated circuit device according to some embodiments of the present disclosure.

FIG. 3B is an enlarged view of the integrated circuit device of FIG. 3A.

FIG. 4 is a cross-sectional view of a portion of a parallel-type capacitor in an integrated circuit according to some embodiments of the present disclosure.

FIG. 5A is a schematic view of a cross-type capacitor in an integrated circuit according to some embodiments of the present disclosure.

FIG. 5B is a schematic top view of the cross-type capacitor of FIG. 5A.

FIG. 5C is a schematic cross-sectional view of the cross-type capacitor taken along line C-C in FIG. 5B.

FIG. 5D is a schematic cross-sectional view of the cross-type capacitor taken along line D-D in FIG. 5B.

FIG. 6 is a cross-sectional view of a portion of a cross-type capacitor in an integrated circuit according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.”

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 130rees or at other orientations) and the spatially relative descriptors used herein may likewise be interpreted accordingly.

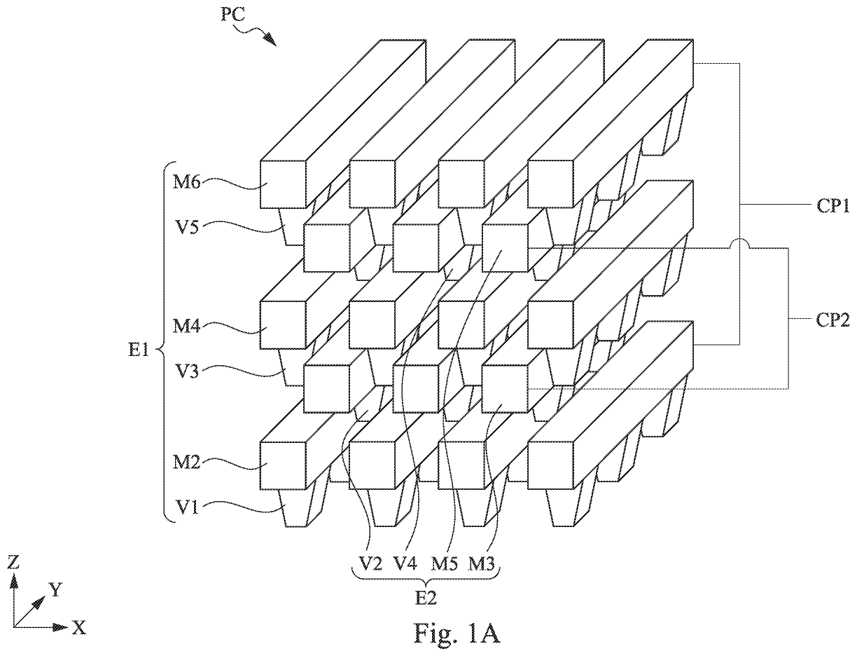

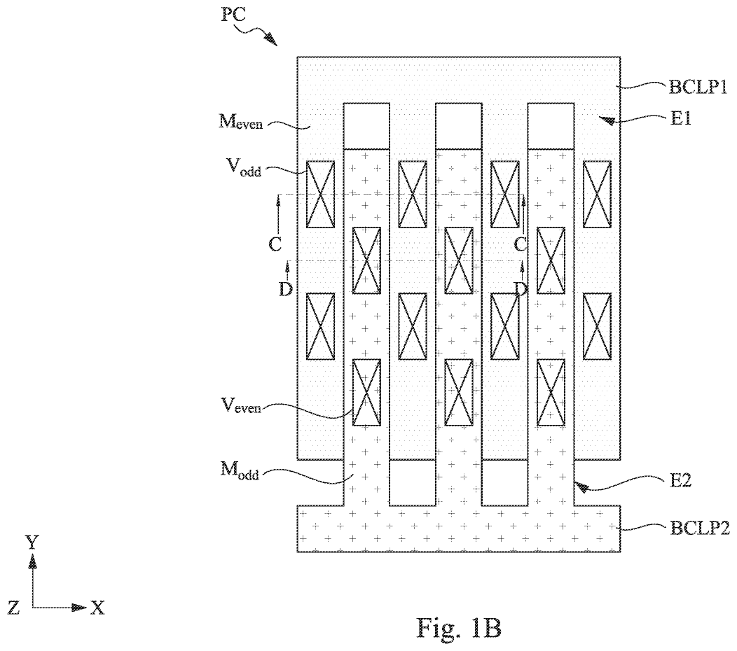

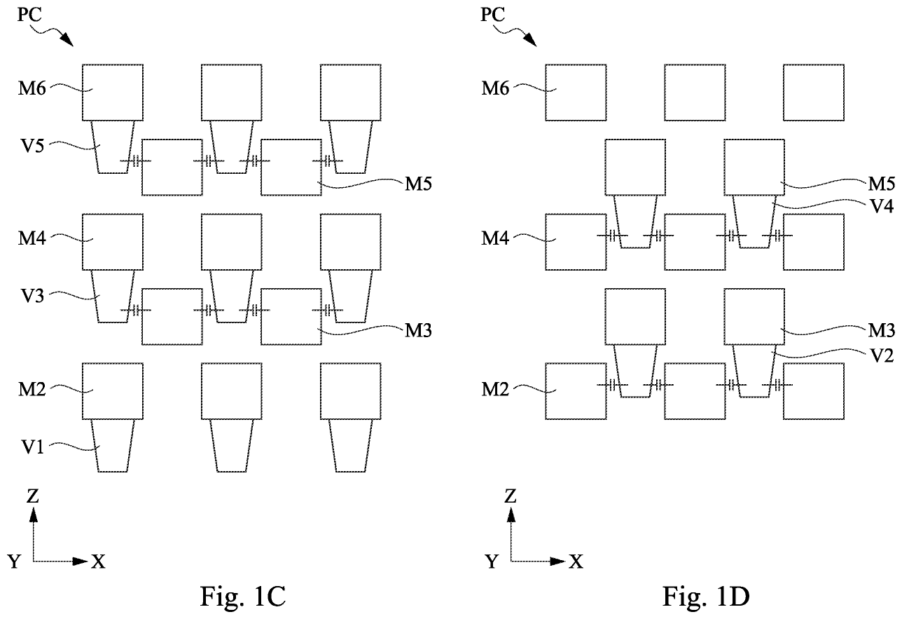

FIG. 1A is a schematic view of a parallel-type capacitor PC in an integrated circuit according to some embodiments of the present disclosure. FIG. 1B is a schematic top view of the parallel-type capacitor PC of FIG. 1A. FIG. 1C is a schematic cross-sectional view of the parallel-type capacitor PC taken along line C-C in FIG. 1B. FIG. 1D is a schematic cross-sectional view of the parallel-type capacitor PC taken along line D-D in FIG. 1B. As depicted, a metallization stack includes plural metallization layers (e.g., the metallization layer M2-M6) is shown. In some embodiments, the parallel-type capacitor PC may be a three-dimension (3D) structure including a first electrode E1, a second electrode E2, and one or more dielectric materials between the first electrode E1 and the second electrode E2. The first electrode E1 may include metal lines of the even-numbered metallization layers M2, M4, and M6 and metal vias V1, V3, and V5 respectively connected to bottoms of the metal lines of the even-numbered metallization layers M2, M4, and M6, for example, through the conductive path CL1. The second electrode E2 may include metal lines of the odd-numbered metallization layers M3 and M5 and metal vias V2 and V4 respectively connected to bottoms of the metal lines of the odd-numbered metallization layers M3 and M5, for example, through the conductive path CL1. By using metal lines of the metallization layers as the first and second electrodes E1 and E2 of the parallel-type capacitor PC, the capacitor cell area can be shrunk, thereby saving chip are and enhancing reliability.

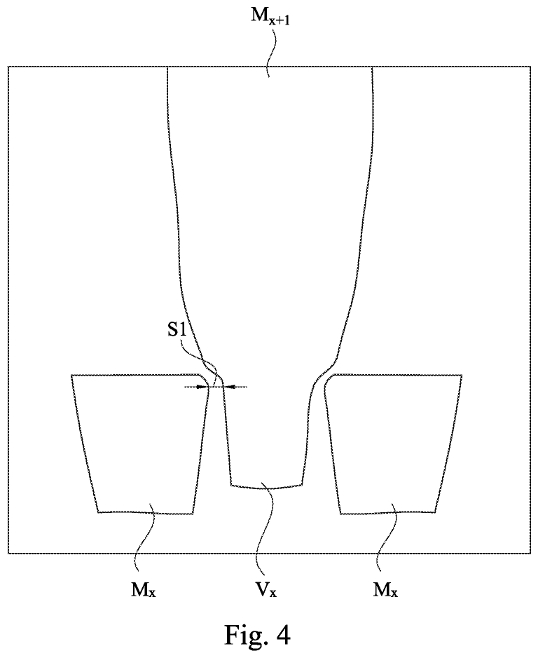

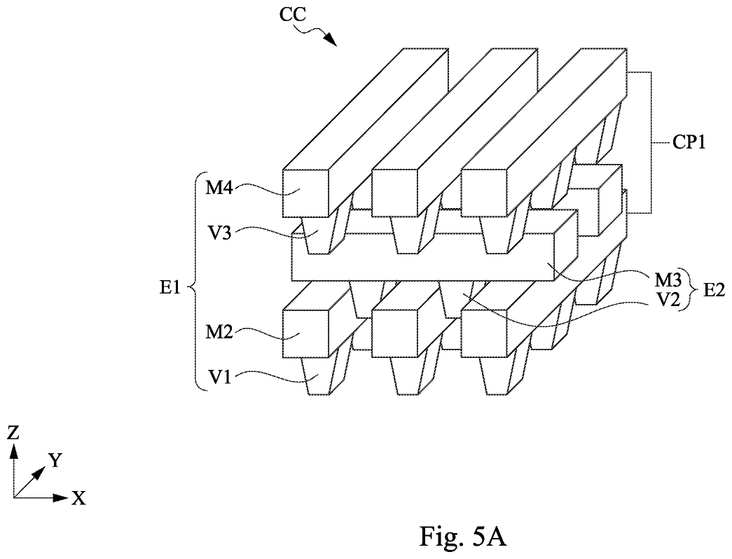

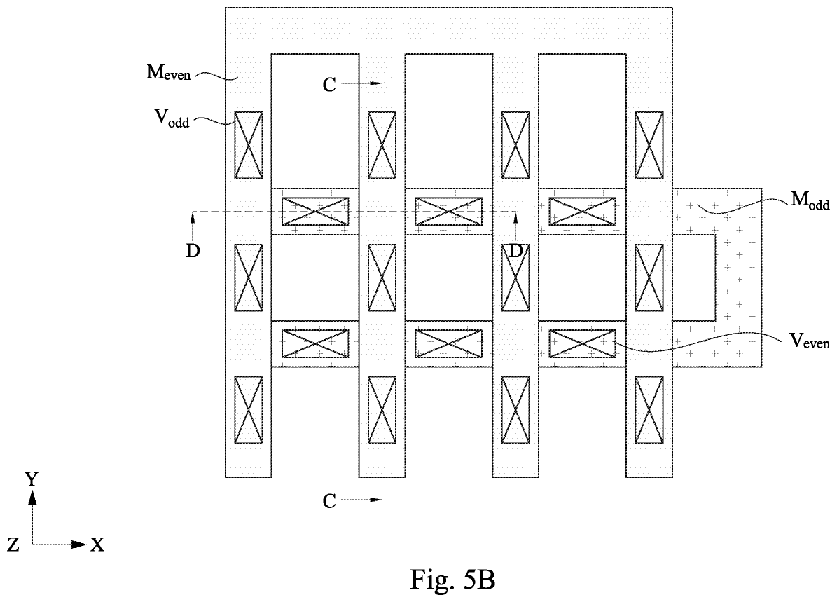

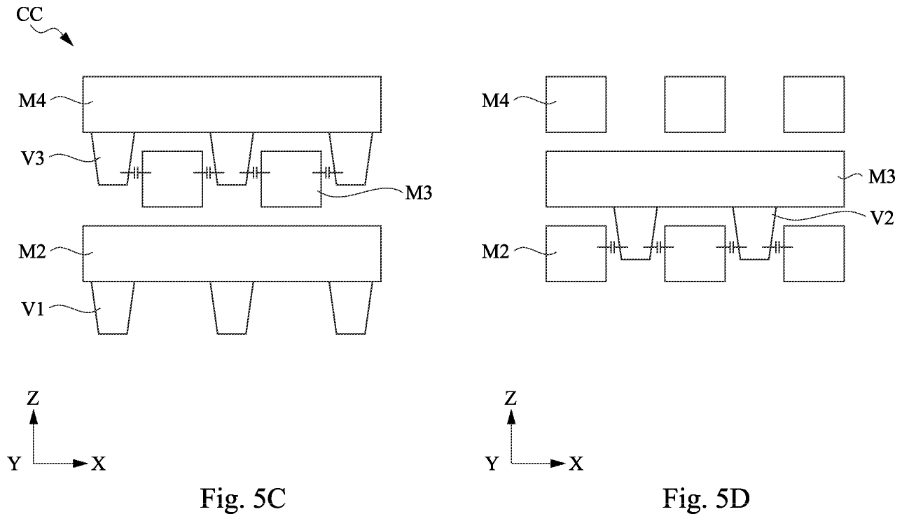

For the parallel-type capacitor PC, the metal lines in the metallization layers Mₑᵥₑₙ extend substantially along a direction parallel with an extension direction of the metal lines in the metallization layers M_{odd}. The even-numbered metallization layers M2, M4, and M6 can be referred to as metallization layers Mₑᵥₑₙ, and the odd-numbered metallization layers M3 and M5 can be referred to as metallization layers M_{odd}. And, the metal vias V1, V3, and V5 can be referred to as metal vias V_{odd}, and the metal vias V2 and V4 can be referred to as metal vias Vₑᵥₑₙ. For example, in FIG. 5B, the metal lines in the metallization layers Mₑᵥₑₙ and metal lines in the metallization layers M_{odd} extend substantially along the direction Y, and the metal lines in the metallization layers Mₑᵥₑₙ and metal lines in the metallization layers M_{odd} are interlaced with each other along the direction X, in which the direction X is substantially orthogonal to the direction Y.

In the present embodiments, since the metal lines in the metallization layers Mₑᵥₑₙ and metal lines in the metallization layers M_{odd} are interlaced with each other, the metal vias Vₑᵥₑₙ and V_{odd} may be misaligned with each other along the direction Y in FIG. 1B. In the present embodiments, the metal vias Vₑᵥₑₙ and V_{odd} may be misaligned with each other along the direction X in FIG. 1B. In some other embodiments, the metal vias Vₑᵥₑₙ and V_{odd} may aligned with each other along the direction X in FIG. 1B. Each of the metallization layers Mₑᵥₑₙ in the first electrode E1 may include a bus conductive line BCLP1 connecting the metal lines in the layer to each other. Each of the metallization layers M_{odd} in the second electrode E2 may include a bus conductive line BCLP2 connecting the metal lines in the layer to each other.

In some embodiments of the present embodiments, as tops of the metal vias V2-V5 are respectively connected to bottom surfaces of the metal lines of the metallization layers M3-M6 thereabove, the metal vias V2-V5 are respectively inserted into the space of the metal line of the underlying metallization layers M2-M5 and misaligned with the metal lines of the underlying metallization layers M2-M5. In some embodiments, bottoms of the metal vias V2-V5 are respectively below top surfaces of the underlying metallization layers M2-M5. The metal vias V2-V5 may not overlap the underlying metallization layers M2-M5, thereby being spaced apart from the underlying metallization layers M2-M5. A space S1 between the metal vias V2-V5 and the metal line of the metallization layers M2-M5 may be in nanoscale. The space S1 may be less than a width of the metal line of the metallization layers M2-M5 or a space between the metal lines of the metallization layers M2-M5. The space S1 between the metal vias V2-V5 and the metal line of the metallization layers M2-M5 can be referred to as clearance (CL). By reducing the clearance, the capacitance density of the capacitor PC can be increased. The clearance of the capacitor PC can be optimized for increasing capacitance density, inhibiting leakage current and improving reliability.

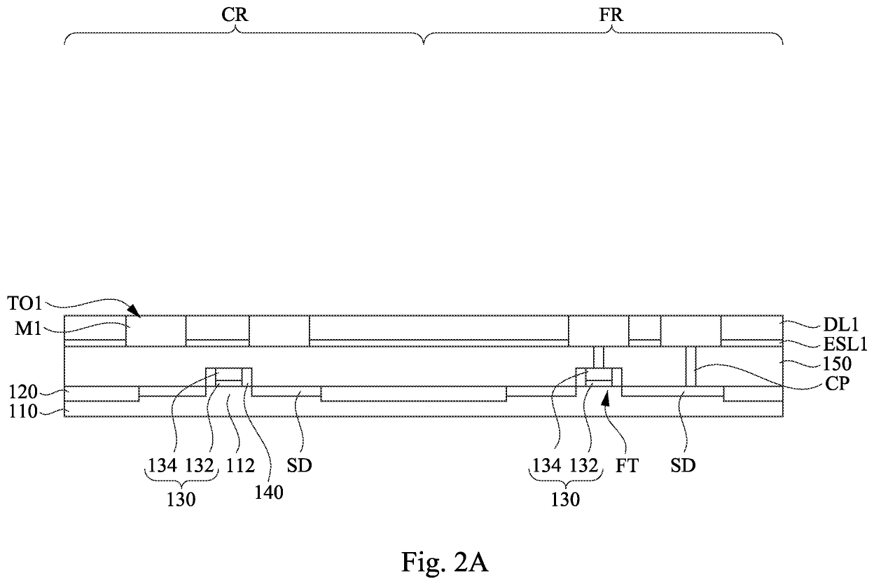

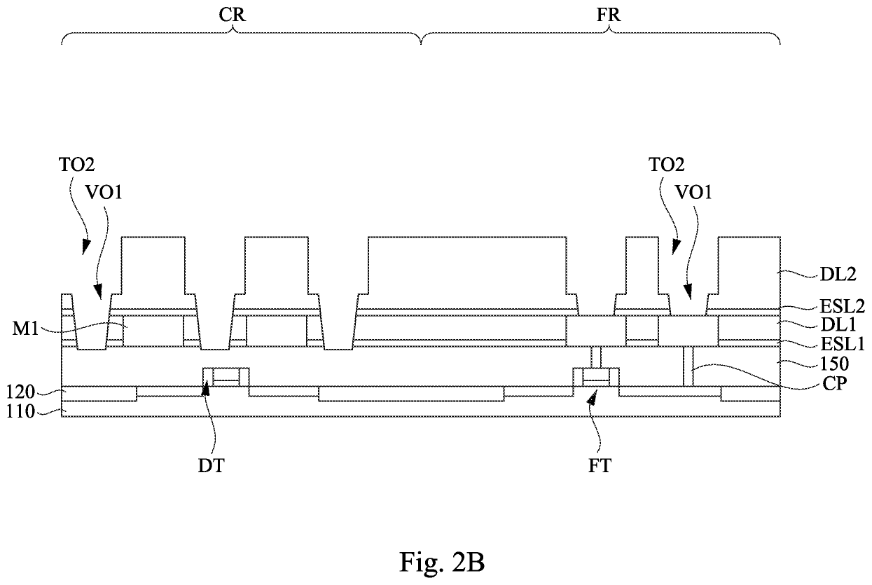

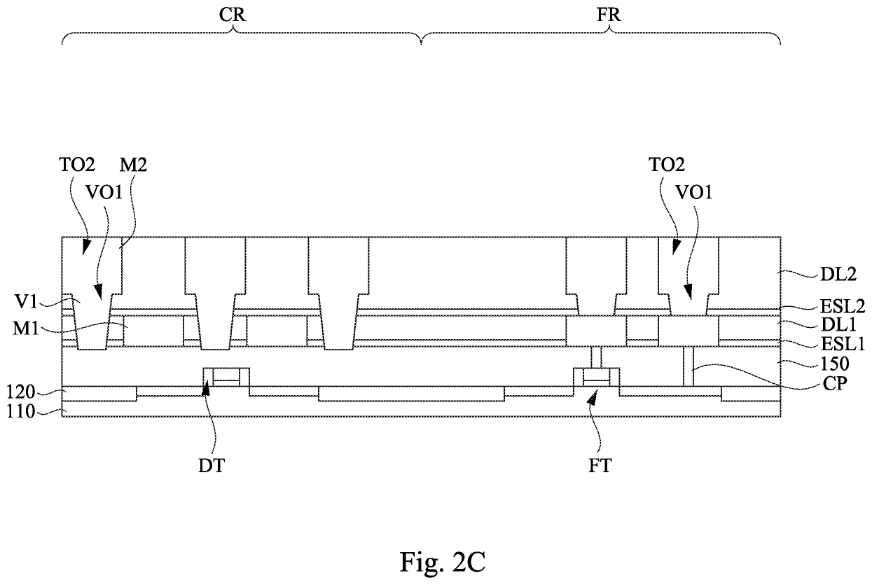

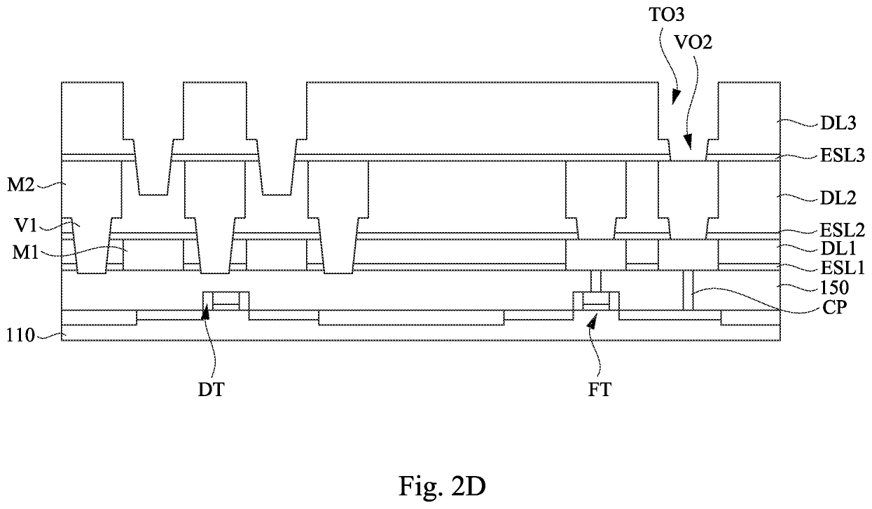

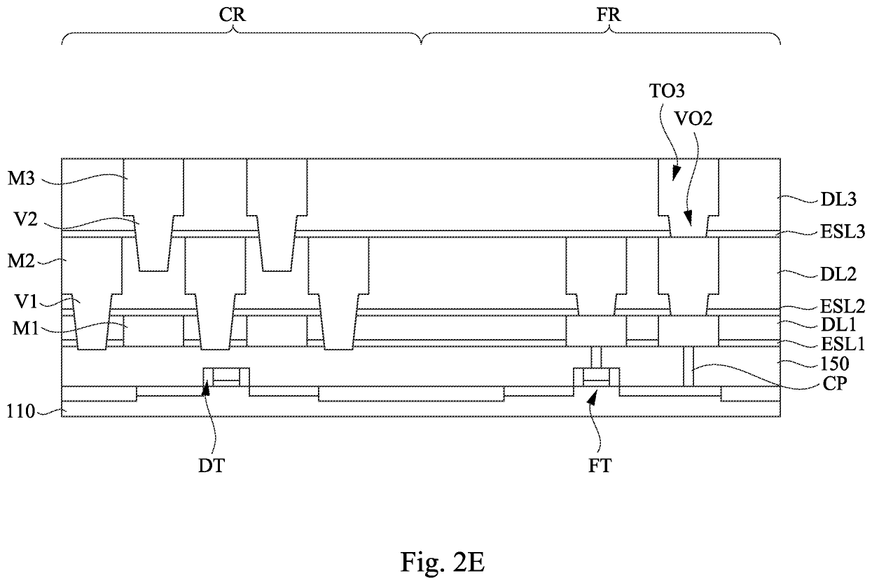

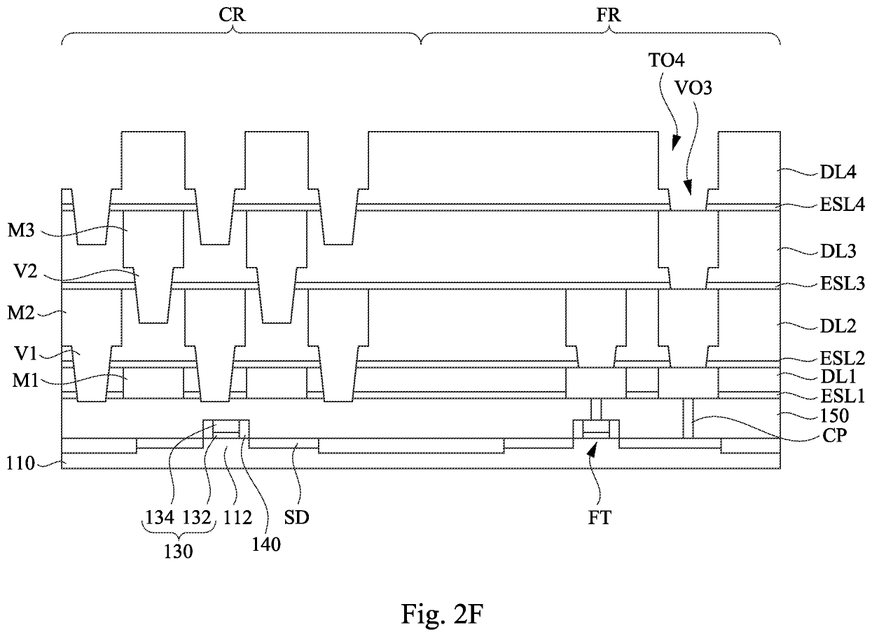

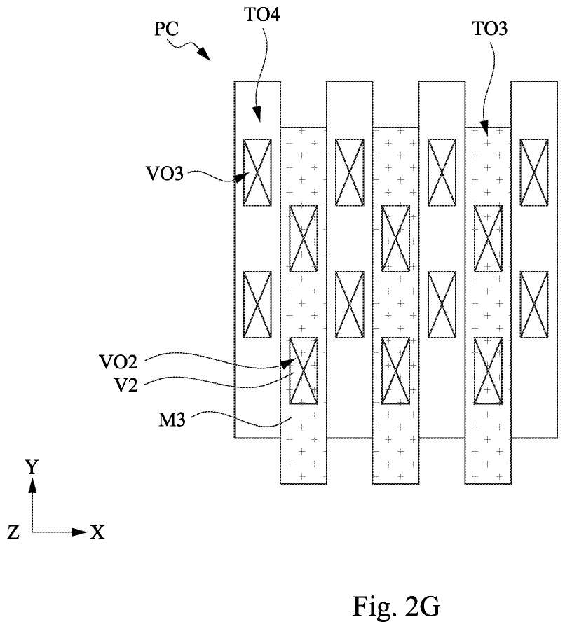

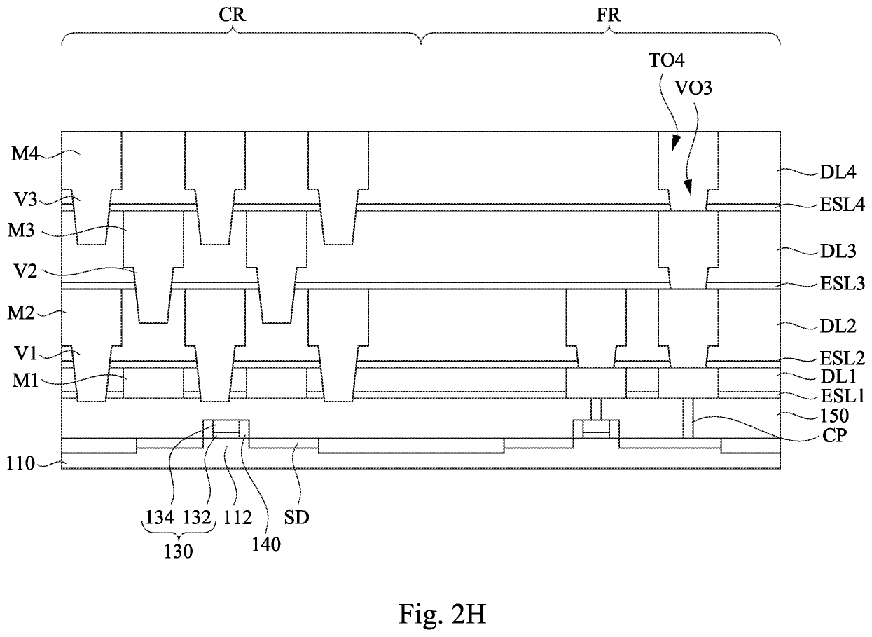

FIGS. 2A-2H illustrate a method for fabricating an integrated circuit device at various intermediate stages of manufacture according to some embodiments of the present disclosure. FIGS. 2A-2F and 2H illustrate cross-sectional views of the integrated circuit device at various intermediate stages, respectively. FIG. 2G illustrates a top view of a portion of the integrated circuit device illustrated in FIG. 2F. FIG. 21 illustrates a top view of a portion of the integrated circuit device illustrated in FIG. 2H. FIG. 21 illustrates a top view of a portion of the integrated circuit device illustrated in FIG. 2H. It is understood that additional operations may be provided before, during, and after the operations shown by FIGS. 2A-2H, and some of the operations described below can be replaced or eliminated for additional embodiments of the method. The order of the operations/processes may be interchangeable.

Reference is made to FIG. 2A. In some embodiments, a substrate 110 is provided. The substrate 110 may comprise a substantially monocrystalline material, for example, bulk silicon. In some other embodiments, the substrate 110 may include another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. In some embodiments, the substrate 110 may comprise an active layer of a semiconductor-on-insulator (SOI) substrate. An SOI substrate comprises a layer of a semiconductor material, such as silicon, formed on an insulator layer. The insulator layer may be, for example, a buried oxide (BOX) layer or a silicon oxide layer. The insulator layer is provided on a substrate, such as a silicon or glass substrate. Other substrates, such as multi-layered or gradient substrates, may also be used. The substrate 110 may include a functional region FR where functional devices and functional circuits are formed and a capacitor region CR where a capacitor is to be formed.

In some embodiments, one or more active and/or passive devices are formed on the substrate 110. For example, the functional devices FT and the dummy devices DT are formed in the functional region FR and the capacitor region CR, respectively. The dummy devices DT may have a geometry similar to that of the functional devices FT for addressing loading issues during the process, but not be connected to the functional circuits. In the depicted embodiments, the devices FT and DT are fin field-effect transistors (FinFET) that are three-dimensional MOSFET structure formed in fin-like strips of semiconductor protrusions referred to as fins 112. The cross-section shown in FIG. 2A is taken along a longitudinal axis of the fin 112 in a direction parallel to the direction of the current flow between the source/drain regions SD. The fin 112 may be formed by patterning the substrate 110 using photolithography and etching techniques. For example, a spacer image transfer (SIT) patterning technique may be used. In this method a sacrificial layer is formed over a substrate and patterned to form mandrels using suitable photolithography and etch processes. Spacers are formed alongside the mandrels using a self-aligned process. The sacrificial layer is then removed by an appropriate selective etch process. Each remaining spacer may then be used as a hard mask to pattern the respective fin 112 by etching a trench into the substrate 110 using, for example, reactive ion etching (RIE). FIG. 2A illustrates a single fin 112, although the substrate 110 may comprise any number of fins. In some other embodiments, the devices FT and DT can be planar transistors or gate-all-around (GAA) transistors. The GAA transistor may be fabricated by channel stacking techniques, and stacked nanosheet (NS) can enhance the lon at fixed footprint.

STI regions 120 are formed on opposing sidewalls of the fin 112 as illustrated in FIG. 2A. STI regions 120 may be formed by depositing one or more dielectric materials (e.g., silicon oxide) to completely fill the trenches around the fins and then recessing the top surface of the dielectric materials. The dielectric materials of the STI regions 120 may be deposited using a high density plasma chemical vapor deposition (HDP-CVD), low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 120 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 120 such that an upper portion of fins 112 protrudes from surrounding insulating STI regions 120. In some cases, the patterned hard mask used to form the fins 112 may also be removed by the planarization process.

In some embodiments, a gate structure 130 of the FinFET devices FT and DT illustrated in FIG. 2A is a high-k, metal gate (HKMG) gate structure that may be formed using a gate-last process flow. In a gate-last process flow, a sacrificial dummy gate structure (not shown) is formed after forming the STI regions 120. The dummy gate structure may comprise a dummy gate dielectric, a dummy gate electrode, and a hard mask. First a dummy gate dielectric material (e.g., silicon oxide, silicon nitride, or the like) may be deposited. Next, a dummy gate material (e.g., amorphous silicon, polycrystalline silicon, or the like) may be deposited over the dummy gate dielectric and then planarized (e.g., by CMP). A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins and extend between the fins over the surface of the STI regions 120. As described in greater detail below, the dummy gate structure may be replaced by the HKMG gate structure 130 as illustrated in FIG. 2A. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

In FIG. 2A, source/drain regions SD and spacers 140 of the transistor device FT and DT are formed, for example, self-aligned to the dummy gate structures. Spacers 140 may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 140 along the sidewalls of the dummy gate structures extending laterally onto a portion of the surface of the fin 112.

Source/drain regions SD are semiconductor regions in direct contact with the semiconductor fin 112. In some embodiments, the source/drain regions SD may comprise heavily-doped regions and relatively lightly-doped drain extensions, or LDD regions. Generally, the heavily-doped regions are spaced away from the dummy gate structures using the spacers 140, whereas the LDD regions may be formed prior to forming spacers 140 and, hence, extend under the spacers 140 and, in some embodiments, extend further into a portion of the semiconductor fin 112 below the dummy gate structure. The LDD regions may be formed, for example, by implanting dopants (e.g., As, P, B, In, or the like) using an ion implantation process.

The source/drain regions SD may comprise an epitaxially grown region. For example, after forming the LDD regions, the spacers 140 may be formed and, subsequently, the heavily-doped source and drain regions may be formed self-aligned to the spacers 140 by first etching the fins to form recesses, and then depositing a crystalline semiconductor material in the recess by a selective epitaxial growth (SEG) process that may fill the recess and may extend further beyond the original surface of the fin 112 to form raised source/drain epitaxy structures. The crystalline semiconductor material may be elemental (e.g., Si, or Ge, or the like), or an alloy (e.g., Sil-xCx, or Sil-xGex, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 1014 cm-2 to 1016 cm-2) of dopants may be introduced into the heavily-doped source and drain regions SD either in situ during SEG, or by an ion implantation process performed after the SEG, or by a combination thereof.

Once the source/drain regions SD are formed, a first interlayer dielectric (ILD) layer (e.g., lower portion of the ILD layer 150) is deposited over the source/drain regions SD. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the first ILD layer. The HKMG gate structures 130, illustrated in FIG. 2A, may then be formed by first removing the dummy gate structures using one or more etching techniques, thereby creating recesses between respective spacers 140. Next, a replacement gate dielectric layer 132 comprising one more dielectrics, followed by a replacement gate metal layer 134 comprising one or more metals, are deposited to completely fill the recesses. Excess portions of the gate dielectric layer 132 and the gate metal layer 134 may be removed from over the top surface of first ILD using, for example, a CMP process. The resulting structure, as illustrated in FIG. 2A, may include remaining portions of the gate dielectric layer 132 and the gate metal layer 134 inlaid between respective spacers 140.

The gate dielectric layer 132 includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the gate metal layer 134 may be a multilayered metal gate stack comprising a barrier layer, a work function layer, and a gate-fill layer formed successively on top of gate dielectric layer 132. Example materials for a barrier layer include TiN, TaN, Ti, Ta, or the like, or a multilayered combination thereof. A work function layer may include TIN, TaN, Ru, Mo, Al, for a p-type FET, and Ti, Ag, TaAl, TaAIC, TiAIN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, PVD, ALD, PEALD, electrochemical plating (ECP), electroless plating and/or the like.

After forming the HKMG gate structure 130, a second ILD layer (e.g., upper portion of the ILD layer 150) is deposited over the first ILD layer, and these ILD layers are in combination referred to as the ILD layer 150, as illustrated in FIG. 2A. In some embodiments, the insulating materials to form the first ILD layer and the second ILD layer may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer and the second ILD layer may be deposited using any suitable method, such as CVD, PVD, ALD, PEALD, PECVD, SACVD, FCVD, spin-on, and/or the like, or a combination thereof.

The contact plugs CP may be formed in the ILD layer 150 using photolithography, etching and deposition techniques. For example, a patterned mask may be formed over the ILD layer 150 and used to etch openings that extend through the ILD layer 150 to expose the gate structure 130 as well as the source/drain regions SD. Thereafter, conductive liner may be formed in the openings in the ILD layer 150. Subsequently, the openings are filled with a conductive fill material. The liner comprises barrier metals used to reduce out-diffusion of conductive materials from the contact plugs CP into the surrounding dielectric materials. In some embodiments, the liner may comprise two barrier metal layers. The first barrier metal comes in contact with the semiconductor material in the source/drain regions SD and may be subsequently chemically reacted with the heavily-doped semiconductor in the source/drain regions SD to form a low resistance ohmic contact, after which the unreacted metal may be removed. For example, if the heavily-doped semiconductor in the source/drain regions SD is silicon or silicon-germanium alloy semiconductor, then the first barrier metal may comprise Ti, Ni, Pt, Co, other suitable metals, or their alloys, and may form silicide with the source/drain regions SD. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a planarization process (e.g., CMP) may be used to remove excess portions of all the conductive materials from over the surface of the ILD layer 150. The resulting conductive plugs extend into the ILD layer 150 and constitute contact plugs CP making physical and electrical connections to the gates and/or source/drain nodes of electronic devices, such as the tri-gate FinFET device FT illustrated in FIG. 2A. After the formation of the contact plugs CP, an etch stop layer ESL1 is deposited over the ILD layer 150 and the contact plugs CP, and then an ILD layer DL1 is deposited over the etch stop layer ESL1.

A metallization layer M1 including plural metal lines is formed in the ILD layer DL1. Formation of the metallization layer M1 may include etching trench openings TO1 in the ILD layer DL1, removing a portion of the etch stop layer ESL1 exposed by the trench openings TO1 in the ILD layer DL1 to make the trench openings TO1 exposing the underlying contact plug CP, and depositing one or more conductive materials into the trench openings TO1 in the ILD layer DL1 and the etch stop layer ESL1. In some embodiment, prior to etching the trench openings TO1, a patterned mask is formed over the ILD layer DL1 by photolithography for serving as etch mask during etching the trench openings TO1. The patterned mask may be a photoresist mask or photoresist mask with a hard mask therebelow. A planarization process (e.g., a chemical mechanical polish (CMP)) may be performed to remove an excess portion of the conductive materials from the trench openings TO1 in the ILD layer DL1. Remaining portions of the conductive materials in the trench openings TO1 in the ILD layer DL1 form the metallization layer M1.

Reference is made to FIG. 2B. An etch stop layer ESL2 may be deposited over the structure of FIG. 2A, and then an ILD layer DL2 may be deposited over the etch stop layer ESL2. In some embodiments, one or more etching/cleaning processes is performed to remove materials of the ILD layer DL2, the etch stop layer ESL2, the ILD layer DL1, and the etch stop layer ESL1, thereby forming trench openings TO2 and via openings VO1 in these layers. The etching/cleaning processes may include a trench etch process for the trench openings TO2 and a via etch process for the via openings VO1. In some embodiment, prior to the trench etch process, a trench patterned mask is formed over the ILD layer DL2 by photolithography for serving as etch mask during etching the trench etch process. In some embodiment, prior to the via etch process, a via patterned mask is formed over the et ILD layer DL2 by photolithography for serving as etch mask during etching the via etch process. The trench patterned mask and the via patterned mask may be a photoresist mask or photoresist mask with a hard mask therebelow. In some embodiments, the via etch process may be performed after the trench etch process. In some embodiments, the trench etch process may be performed after the via etch process.

In some embodiments of the present disclosure, in the region FR, the via openings VO1 are aligned with the metal lines in the metallization layer M1; and in the region CR, the via openings VO1 are misaligned with the metal lines in the metallization layer M1. As a result, the via openings VO1 in the regions FR and CR can be etched by a same via etch process with different profiles. For example, in the region FR, since the metallization layer M1 may have a higher etch resistance to the via etch process, with the metallization layer M1 directly below the via openings VO1, the via openings VO1 can be etched to expose a top surface of the metallization layer M1, and the underlying layers below the metallization layer M1 are not etched by the via etch process. In the region CR, in absence of the metallization layer M1 directly below the via openings VO1, the via openings VO1 can be etched at a position laterally aligned to the metallization layer M1 (e.g., vertically between bottom and top surfaces of the metallization layer M1). For example, the via openings VO1 can be etched into the ILD layer DL1. In some embodiments, the via opening can may be further etched till at a position below a bottom surface of the metallization layer M1. For example, the via openings VO1 can be etched into the ILD layer DL1, optionally into the etch stop layer ESL1, and optionally into the ILD layer 150.

Reference is made to FIG. 2C. One or more conductive materials are deposited into the trench openings TO2 and the via openings VO1, followed by a planarization process (e.g., a chemical mechanical polish (CMP)). The planarization process may be performed to remove an excess portion of the conductive materials from the trench openings TO2 and the via openings VO1 in the ILD layer DL2. Remaining portions of the conductive materials in the trench openings TO2 and the via openings VO1 in the ILD layer DL2 form the metallization layer M2 and the metal vias V1, respectively.

According to the profile of the via openings VO1, the metal vias V1 in the region FR may connect the metallization layer M2 to the metallization layer M1, and the metal vias V1 in the region CR may have a bottom surface below the top surface of the metallization layer M1. In some embodiments, the bottom surface of the metal vias V1 in the region CR may be below a level at three-quarter height of the metallization layer M1, or even below a level at half height of the metallization layer M1. In some embodiments, the bottom surface of the metal vias V1 in the region CR may be below the bottom surface of the metallization layer M1. The bottom surface of the metal vias V1 in the region CR may be in contact with the ILD layer 150 in some embodiments. In some alternative embodiments, the bottom surface of the metal vias V1 in the region CR may be at a same level as a bottom surface of the metallization layer M1. In some alternative embodiments, the bottom surface of the metal vias V1 in the region CR may be laterally aligned with the metallization layer M1. For example, the bottom surface of the metal vias V1 in the region CR may be at a vertical level between the top and bottom surfaces of the metallization layer M1.

Reference is made to FIG. 2D. An etch stop layer ESL3 may be deposited over the structure of FIG. 2C, and then an ILD layer DL3 may be deposited over the etch stop layer ESL3. In some embodiments, one or more etching/cleaning processes is performed to remove materials of the ILD layer DL3, the etch stop layer ESL3, and the ILD layer DL2, thereby forming trench openings TO3 and via openings VO2 in these layers. The etching/cleaning processes may include a trench etch process for the trench openings TO3 and a via etch process for the via openings VO2. In some embodiment, prior to the trench etch process, a trench patterned mask is formed over the ILD layer DL3 by photolithography for serving as etch mask during etching the trench etch process. In some embodiment, prior to the via etch process, a via patterned mask is formed over the ILD layer DL3 by photolithography for serving as etch mask during etching the via etch process. The trench patterned mask and the via patterned mask may be a photoresist mask or photoresist mask with a hard mask therebelow. In some embodiments, the via etch process may be performed after the trench etch process. In some embodiments, the trench etch process may be performed after the via etch process.

In some embodiments of the present disclosure, in the region FR, the via openings VO2 are aligned with the metal lines in the metallization layer M2; and in the region CR, the via openings VO2 are misaligned with the metal lines in the metallization layer M2. As a result, the via openings VO2 in the regions FR and CR can be etched by a same via etch process with different profiles. For example, in the region FR, since the metallization layer M2 may have a higher etch resistance to the via etch process, with the metallization layer M2 directly below the via openings VO2, the via openings VO2 can be etched through the ILD layer DL3 and the etch stop layer ESL3 to expose a top surface of the metallization layer M2, and the underlying layers below the metallization layer M2 are not etched by the via etch process. In the region CR, in absence of the metallization layer M2 directly below the via openings VO2, the via openings VO2 can be etched through the ILD layer DL3 and the etch stop layer ESL3 and into the ILD layer DL2. In the present embodiments, the via openings VO2 may be etched till at a position laterally aligned to the metallization layer M2 (e.g., vertically between bottom and top surfaces of the metallization layer M2). For example, the via openings VO2 can be etched into the ILD layer DL2. In some alternatively embodiments, the via openings VO2 may be further etched till at a position below a bottom surface of the metallization layer M2. For example, the via openings VO2 can be etched into the ILD layer DL2, and optionally into the etch stop layer ESL2.

Reference is made to FIG. 2E. One or more conductive materials are deposited into the trench openings TO3 and the via openings VO2, followed by a planarization process (e.g., a chemical mechanical polish (CMP)). The planarization process may be performed to remove an excess portion of the conductive materials from the trench openings TO3 and the via openings VO2 in the ILD layer DL3. Remaining portions of the conductive materials in the trench openings TO3 and the via openings VO2 in the ILD layer DL3 form the metallization layer M3 and the metal vias V2, respectively.

According to the profile of the via openings VO2, the metal vias V2 in the region FR may connect the metallization layer M3 to the metallization layer M2, and the metal vias V2 in the region CR may have a bottom surface below the top surface of the metallization layer M2. In some embodiments, the bottom surface of the metal vias V2 in the region CR may be laterally aligned with the metallization layer M2. For example, the bottom surface of the metal vias V2 in the region CR may be at a vertical level between the top and bottom surfaces of the metallization layer M2. In some embodiments, the bottom surface of the metal vias V2 in the region CR may be below a level at three-quarter height of the metallization layer M2, or even below a level at half height of the metallization layer M2. In some embodiments, the bottom surface of the metal vias V2 in the region CR may be at a same level as a bottom surface of the metallization layer M2. In some embodiments, the bottom surface of the metal vias V2 in the region CR may be below the bottom surface of the metallization layer M2.

Reference is made to FIGS. 2F and 2G. An etch stop layer ESL4 may be deposited over the structure of FIG. 2E, and then an ILD layer DL4 may be deposited over the etch stop layer ESL4. In some embodiments, one or more etching/cleaning processes is performed to remove materials of the ILD layer DL4, the etch stop layer ESL4, and the ILD layer DL3, thereby forming trench openings TO4 and via openings VO3 in these layers. The etching/cleaning processes may include a trench etch process for the trench openings TO3 and a via etch process for the via openings VO3. In some embodiment, prior to the trench etch process, a trench patterned mask is formed over the ILD layer DL4 by photolithography for serving as etch mask during etching the trench etch process. In some embodiment, prior to the via etch process, a via patterned mask is formed over the ILD layer DL4 by photolithography for serving as etch mask during etching the via etch process. The trench patterned mask and the via patterned mask may be a photoresist mask or photoresist mask with a hard mask therebelow. In some embodiments, the via etch process may be performed after the trench etch process. In some embodiments, the trench etch process may be performed after the via etch process.

In some embodiments of the present disclosure, in the region FR, the via openings VO3 are aligned with the metal lines in the metallization layer M3; and in the region CR, the via openings VO3 are misaligned with the metal lines in the metallization layer M3. As a result, the via openings VO3 in the regions FR and CR can be etched by a same via etch process with different profiles. For example, in the region FR, since the metallization layer M3 may have a higher etch resistance to the via etch process, with the metallization layer M3 directly below the via openings VO3, the via openings VO3 can be etched through the ILD layer DL4 and the etch stop layer ESL4 to expose a top surface of the metallization layer M3, and the underlying layers below the metallization layer M3 are not etched by the via etch process. In the region CR, in absence of the metallization layer M3 directly below the via openings VO3, the via openings VO3 can be etched through the ILD layer DL4 and the etch stop layer ESL4 and into the ILD layer DL3. In the present embodiments, the via openings VO3 may be etched till at a position laterally aligned to the metallization layer M3 (e.g., vertically between bottom and top surfaces of the metallization layer M3). For example, the via openings VO3 can be etched into the ILD layer DL3. In some alternatively embodiments, the via openings VO3 may be further etched till at a position below a bottom surface of the metallization layer M3. For example, the via openings VO3 can be etched into the ILD layer DL3, and optionally into the etch stop layer ESL3.

Reference is made to FIGS. 2H and 21. One or more conductive materials are deposited into the trench openings TO4 and the via openings VO3, followed by a planarization process (e.g., a chemical mechanical polish (CMP)). The planarization process may be performed to remove an excess portion of the conductive materials from the trench openings TO4 and the via openings VO3 in the ILD layer DL4. Remaining portions of the conductive materials in the trench openings TO4 and the via openings VO3 in the ILD layer DL4 form the metallization layer M4 and the metal vias V3, respectively.

According to the profile of the via openings VO3, the metal vias V3 in the region FR may connect the metallization layer M4 to the metallization layer M3, and the metal vias V3 in the region CR may have a bottom surface below the top surface of the metallization layer M3. In some embodiments, the bottom surface of the metal vias V3 in the region CR may be laterally aligned with the metallization layer M3. For example, the bottom surface of the metal vias V3 in the region CR may be at a vertical level between the top and bottom surfaces of the metallization layer M3. In some embodiments, the bottom surface of the metal vias V3 in the region CR may be below a level at three-quarter height of the metallization layer M3, or even below a level at half height of the metallization layer M3. In some embodiments, the bottom surface of the metal vias V3 in the region CR may be at a same level as a bottom surface of the metallization layer M3. In some embodiments, the bottom surface of the metal vias V3 in the region CR may be below the bottom surface of the metallization layer M3.

In the fabrication process illustrated in FIGS. 2A-2H, the ILD layer 150 and the ILD layers DL1-DL4 may include a suitable dielectric material different from that of the etch stop layers ESL1-ESL4. For example, the ILD layers DL1-DL4 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The etch stop layers ESL1-ESL4 may include silicon nitride, silicon carbide, other high-k materials, metal oxides, the like, or the combination thereof. The ILD layer 150 and the ILD layers DL1-DL4 and the etch stop layers ESL1-ESL4 can be deposited using any suitable method, such as spin-on coating, CVD, ALD, PVD, the like, or the combination thereof.

In some embodiments, the one or more conductive materials used for the metallization layers M1-M4 and the metal via V1-V3 may include copper (Cu), tungsten (W), aluminum (Al), titanium (Ti), titanium nitride (TiN), tantalum nitride (TaN), Ta, Co, Ru, Mo, Ir, other metal alloy, other metals, the like, or the combination thereof. In some embodiments, one or more barrier/adhesion layers may be deposited prior to depositing the one or more conductive materials. The one or more barrier/adhesion layers may comprise titanium, titanium nitride, tantalum, tantalum nitride, other metal nitrides, other metal carbide, metal oxide, other metals, the like, or the combination thereof, and may be formed using PVD, CVD, ALD, or the like.

As depicted, the integrated circuit and the parallel-type capacitor PC are fabricated using four metallization layers M1-M4 with three layers of metallization vias or interconnects V1 through V3. Other embodiments may contain more or fewer metallization layers and a corresponding more or fewer number of vias. Four ILD layers DL1-DL4 are depicted as spanning the capacitor region CR and the functional region FR. The ILD layers may provide electrical insulation as well as structural support for the various features of the integrated circuit and the parallel-type capacitor PC during many fabrication process steps.

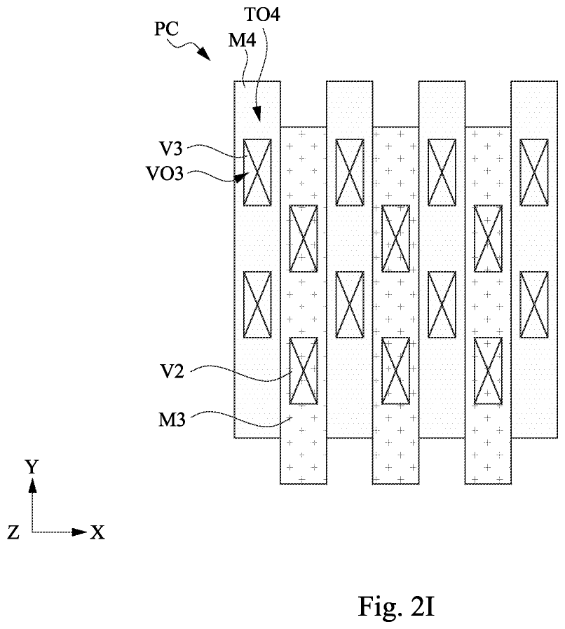

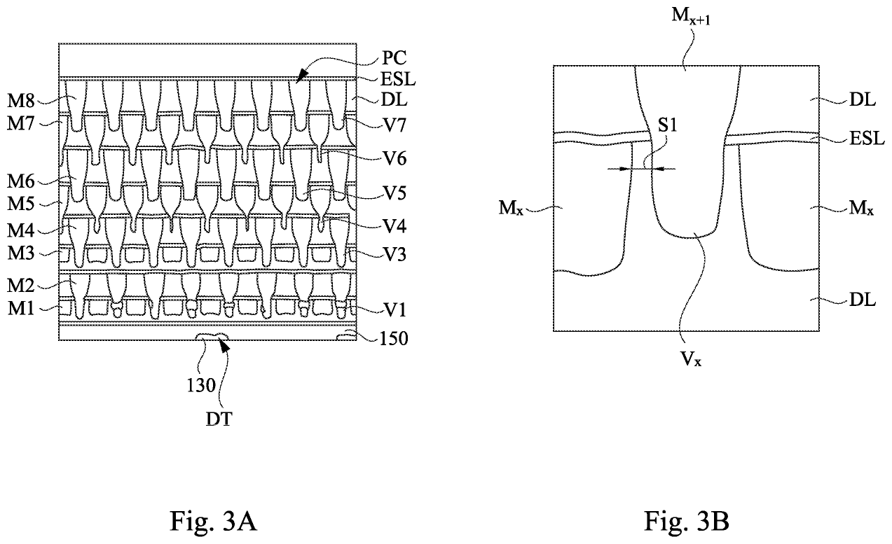

FIG. 3A is a cross-sectional view of an integrated circuit device according to some embodiments of the present disclosure. In the present embodiments, the parallel-type capacitor PC is fabricated using eight metallization layers M1-M8 with seven layers of metallization vias or interconnects V1 through V7. Other embodiments may contain more or fewer metallization layers and a corresponding more or fewer number of vias. Eight ILD layers are DL depicted for providing electrical insulation as well as structural support for the various features of the parallel-type capacitor PC. In FIG. 3A, in some embodiments, the heights of the metallization layers M1-M8 may decreases from top to bottom, and the metallization vias V1 through V7 may maintain to have substantially a same height. As a result, an area that the metallization vias V1 through V7 laterally overlaps the corresponding metallization layers M1-M7 may increase from top to bottom. Stated differently, bottom surfaces of the metallization vias V1 through V7 change from a position higher than a bottom surface of the corresponding metallization layers M1-M7 to a position lower than a bottom surface of the corresponding metallization layers M1-M7 from top to bottom.

FIG. 3B is an enlarged view of the integrated circuit device of FIG. 3A. As illustrated, the metal vias Vₓ and the metal lines of the metallization layers Mₓ can be spaced apart from each other the space S1, which is filled with a portion of the ILD layer DL. The space S1 may be in nanoscale. For example, the space S1 may be in a range from about 16 nanometers to about 32 nanometers. If the space S1 is less than 16 nanometers, the leakage current between the metal vias Vₓ and the metal lines of the metallization layers Mₓ may become serious. If the space S1 is greater than about 32 nanometers, the capacitance density of the capacitor may not be increased.

FIG. 4 is a cross-sectional view of a portion of a parallel-type capacitor in an integrated circuit according to some embodiments of the present disclosure. As described in FIG. 3B, the metal vias Vₓ and the metal lines of the metallization layers Mₓ can be spaced apart from each other the space S1 in nanoscale. Other details are similar to those illustrated above, and therefore not repeated herein.

FIG. 5A is a schematic view of a cross-type capacitor CC in an integrated circuit according to some embodiments of the present disclosure. FIG. 5B is a schematic top view of the cross-type capacitor CC of FIG. 5A. FIG. 5C is a schematic cross-sectional view of the cross-type capacitor CC taken along line C-C in FIG. 5B. FIG. 5D is a schematic cross-sectional view of the cross-type capacitor CC taken along line D-D in FIG. 5B. Details of the present embodiments are similar to those illustrated in FIGS. 1A-1D, except that a cross-type capacitor CC is adopted in the present embodiments. The cross-type capacitor CC may be a three-dimension (3D) structure including a first electrode E1, a second electrode E2, and one or more dielectric materials between the first electrode E1 and the second electrode E2. The first electrode E1 may include metal lines of the even-numbered metallization layers M2 and M4 and metal vias V1 and V3 respectively connected to bottoms of the metal lines of the even-numbered metallization layers M2 and M4. The second electrode E2 may include metal lines of the odd-numbered metallization layers M3 and metal vias V2 respectively connected to bottoms of the metal lines of the odd-numbered metallization layers M3. By using metal lines of the metallization layers as the first and second electrodes E1 and E2 of the cross-type capacitor CC, the capacitor cell area can be shrunk, thereby saving chip are and enhancing reliability.

For the cross-type capacitor CC, the metal lines in the metallization layers Mₑᵥₑₙ extend substantially along a direction crossing an extension direction of the metal lines in the metallization layers M_{odd}. The even-numbered metallization layers M2 and M4 can be referred to as metallization layers Mₑᵥₑₙ, and the odd-numbered metallization layer M3 can be referred to as metallization layers M_{odd}. And, the metal vias V1 and V3 can be referred to as metal vias V_{odd}, and the metal vias V2 can be referred to as metal vias Vₑᵥₑₙ. For example, in FIG. 5B, for the cross-type capacitor CC, the metal lines in the metallization layers Mₑᵥₑₙ extend substantially along the direction Y, and the metal lines in the metallization layers M_{odd} extend substantially along the direction X, in which the direction X and is substantially orthogonal to the direction Y. With the metallization layers Mₑᵥₑₙ and M_{odd} overlapping each other, the cross-type capacitor CC can have a greater capacitance density.

In some embodiments of the present embodiments, as tops of the metal vias V1-V3 are respectively connected to bottom surfaces of the metal lines of the metallization layers M2-M4 thereabove, the metal vias V2 and V3 are respectively inserted into the space of the metal line of the underlying metallization layers M2 and M3 and misaligned with the metal lines of the underlying metallization layers M2 and M3. In some embodiments, bottoms of the metal vias V2 and V3 are respectively below top surfaces of the underlying metallization layers M2 and M3. The metal vias V2 and V3 may not overlap the underlying metallization layers M2 and M3, thereby being spaced apart from the underlying metallization layers M2 and M3. Other details of the cross-type capacitor CC are similar to that of the parallel-type capacitor illustrated above, and therefore not repeated herein.

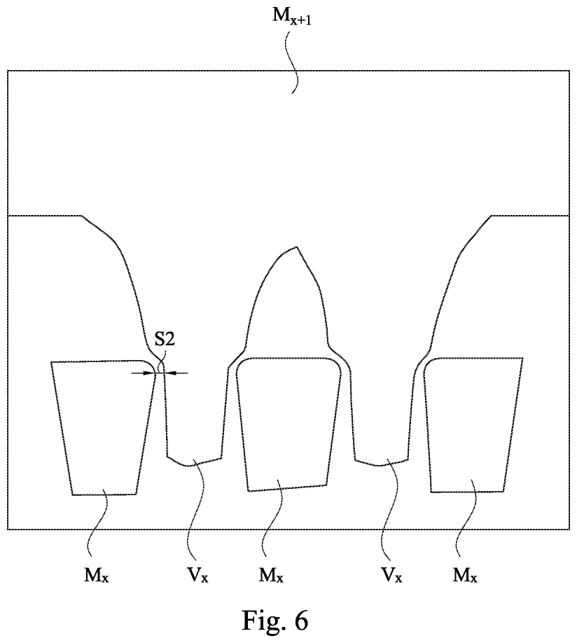

FIG. 6 is a cross-sectional view of a portion of a cross-type capacitor CC in an integrated circuit according to some embodiments of the present disclosure. As illustrated, the metal vias Vₓ and the metal liness of the metallization layers Mₓ can be spaced apart from each other the space S2, which is filled with a portion of the ILD layer DL. The space S2 may be in nanoscale. The space S2 may be referred to as clearance (CL). By reducing the clearance, the capacitance density of the capacitor PC can be increased. The clearance of the capacitor PC can be optimized for increasing capacitance density, inhibiting leakage current and improving reliability. For example, the space S2 may be in a range from 16 nanometers to about 32 nanometers. If the space S1 is less than 16 nanometers, the leakage current between the metal vias Vₓ and the metal lines of the metallization layers Mₓ may become serious. If the space S1 is greater than about 32 nanometers, the capacitance density of the capacitor may not be increased.

For both the parallel-type capacitor and the cross-type capacitor, the number of the even-numbered metallization layers and the number of the odd-numbered metallization layer may vary in a range from 1 to 15. For example, the capacitor may include only one metallization layer serving the first electrode E1 (referring to FIGS. 1A and 5B) and only one metallization layer serving the second electrode E2 (referring to FIGS. 1A and 5B).

Based on the above discussions, it can be seen that the present disclosure offers advantages to the integrated circuit device. It is understood, however, that other embodiments may offer additional advantages, and not all advantages are necessarily disclosed herein, and that no particular advantage is required for all embodiments. One advantage is that metal vias are inserted into the space of metal lines by misaligning metal vias and the metal lines of the bottom metallization layer, thereby forming the nanoscale space between via and metal for providing higher capacitance array cell. Another advantage is that, by shunting the capacitor cell and stacking it in a 3D structure, the capacitor can reach high capacitance density and be fully compatible with logic process and platforms. Still another advantage is that the parallel-type capacitor can ignore the miss-alignment of the via in the direction parallel to the metal. Still another advantage is that the cross-type capacitor gets metal lines overlapping each other, thereby achieving greater capacitance density.

According to some embodiments of the present disclosure, an integrated circuit device includes a first metallization layer, a second metallization layer, and a first metal via. The first metallization layer comprises two adjacent first metal lines. The second metallization layer is over the first metallization layer, wherein the second metallization layer comprises a second metal line. The first metal via is connected with a bottom of the second metal line. The first metal via is between the first metal lines and misaligned with the first metal lines in a top view.

According to some embodiments of the present disclosure, an integrated circuit device includes a transistor and an interconnect structure. The interconnect structure is over the transistor. The interconnect structure comprises a capacitor device includes a first metal line; a second metal line above the first metal line; a first metal via connected with a bottom of the second metal line and having a bottom surface below a top surface of the first metal line.

According to some embodiments of the present disclosure, a method for fabricating an integrated circuit device is provided. The method includes forming a first metallization layer over a substrate, wherein the first metallization layer comprises two adjacent first metal lines; forming a second metallization layer over the first metallization layer, wherein forming the second metallization layer comprises: depositing a dielectric layer over the first metallization layer; etching a trench opening and a via opening communicated with the trench opening in the dielectric layer, wherein the via opening is between the first metal lines and misaligned with the first metal lines in a top view; and depositing a conductive material into the trench opening and the via opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device, comprising:
a first metallization layer comprising two adjacent first metal lines;
a second metallization layer over the first metallization layer, wherein the second metallization layer comprises a second metal line; and
a first metal via connected with a bottom of the second metal line, wherein the first metal via is between the first metal lines and misaligned with the first metal lines in a top view.

2. The integrated circuit device of claim 1, wherein the second metal line is interlaced with the first metal lines in the top view.

3. The integrated circuit device of claim 1, wherein the second metal line extends across the first metal lines in the top view.

4. The integrated circuit device of claim 1, wherein a bottom surface of the first metal via is below a top surface of the first metal lines.

5. The integrated circuit device of claim 1, wherein a bottom surface of the first metal via is below a bottom surface of the first metal lines.

6. The integrated circuit device of claim 1, further comprising:
a dielectric layer between the first metal lines, wherein a bottom surface of the first metal via is in contact with the dielectric layer between the first metal lines.

7. The integrated circuit device of claim 1, wherein a bottom surface of the first metal via is free of contacting the first metal lines.

8. The integrated circuit device of claim 1, further comprising:
a second metal via, wherein the first metallization layer further comprises a third metal line, the second metallization layer further comprises a fourth metal line, and the second metal via connecting the third metal line to the fourth metal line.

9. An integrated circuit device, comprising:
a transistor; and
an interconnect structure over the transistor, wherein the interconnect structure comprises a capacitor device comprising:
a first metal line;
a second metal line above the first metal line; and
a first metal via connected with a bottom of the second metal line and having a bottom surface below a top surface of the first metal line.

10. The integrated circuit device of claim 9, wherein the interconnect structure further comprises
a third metal line at a same level as the first metal line, wherein the third metal line is electrically connected with the transistor;
a fourth metal line at a same level as the second metal line; and
a second metal via connecting the third metal line to the fourth metal line.

11. The integrated circuit device of claim 10, wherein a height of the first metal via is great than a height of the second metal via.

12. The integrated circuit device of claim 9, wherein the bottom surface of the first metal via is below a level at three-quarter height of the first metal line.

13. The integrated circuit device of claim 9, wherein a space between the first metal via and the first metal line is in a range from about 16 nanometers to about 32 nanometers.

14. The integrated circuit device of claim 9, further comprising:
a dummy transistor below the interconnect structure, wherein the dummy transistor is directly below the capacitor device.

15. The integrated circuit device of claim 9, further comprising:
a dielectric layer surrounding the transistor, wherein the bottom surface of the first metal via is in contact with the dielectric layer.

16. The integrated circuit device of claim 9, wherein a height of the second metal line is greater than a height of the first metal line.

17. A method for fabricating an integrated circuit device, comprising:
forming a first metallization layer over a substrate, wherein the first metallization layer comprises two adjacent first metal lines;
forming a second metallization layer over the first metallization layer, wherein forming the second metallization layer comprises:
depositing a dielectric layer over the first metallization layer;
etching a trench opening and a via opening communicated with the trench opening in the dielectric layer, wherein the via opening is between the first metal lines and misaligned with the first metal lines in a top view; and
depositing a conductive material into the trench opening and the via opening.

18. The method of claim 17, wherein etching the via opening is performed such that a bottom of the via opening is laterally aligned with the first metal lines.

19. The method of claim 17, wherein etching the trench opening is performed such that the trench opening extends along an extension direction of the first metal lines.

20. The method of claim 17, wherein etching the via opening is performed such that the trench opening extends across an extension direction of the first metal lines.
